(19) United States
(12) Patent Application Publication
(10) Pub. No.: US 2012/0091304 A1
(43) Pub. Date: Apr. 19, 2012

(54) MOUNTING APPARATUS FOR DATA STORAGE DEVICE

(75) Inventors: KEN-YAO CHUANG, Tu-Cheng (TW); CHIA-WEN TSAI, Tu-Cheng (TW)

(73) Assignee: HON HAI PRECISION INDUSTRY CO., LTD., Tu-Cheng (TW)

(21) Appl. No.: 12/944,771

(22) Filed: Nov. 12, 2010

(30) Foreign Application Priority Data
Oct. 13, 2010 (TW) 99134966

(51) Int. Cl. H05K 7/14; F16B 2/10

(52) U.S. Cl. 248/316.5

(57) ABSTRACT

A mounting apparatus for a data storage device includes a first fixed member, a second fixed member, a torsion spring, and a positioning member. The first fixed member includes a first bottom plate and a first sidewall. The first bottom plate includes a pair of first convex tabs. The pair of first convex tabs each defines a first pin hole therein. The second fixed member includes a second bottom plate and a second sidewall. The second bottom plate includes a pair of second convex tabs. The pair of second convex tabs each defines a second pin hole therein. The positioning member includes a pin. The pin is passed through the first pin holes of the pair of first convex tabs, the second pin holes of the pair of second convex tabs and a center of the torsion spring.

### BACKGROUND

1. Technical Field

The present disclosure relates to device mounting and, particularly, to a mounting apparatus for a data storage device of an electronic device.

2. Description of Related Art

Data storage devices are generally mounted on a bracket via screws and the bracket is then mounted in the computer. To mount the data storage device on the bracket, the bracket is typically deformed, and the data storage device is then received in the bracket. However, the bracket may be damaged due to excessive deformation, impacting cost and convenience.

Therefore, a mounting apparatus is desired to overcome the limitations described.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the present apparatus and a manufacturing method thereof. Moreover, in the drawings, like reference numerals designate corresponding parts throughout the several views.

FIG. 1 is an exploded, isometric view of a mounting apparatus according to an exemplary embodiment.

FIG. 2 is an assembled, isometric view of FIG. 1.

FIG. 3 is an assembled, isometric view of FIG. 1 with a data storage device installed therein.

### DETAILED DESCRIPTION

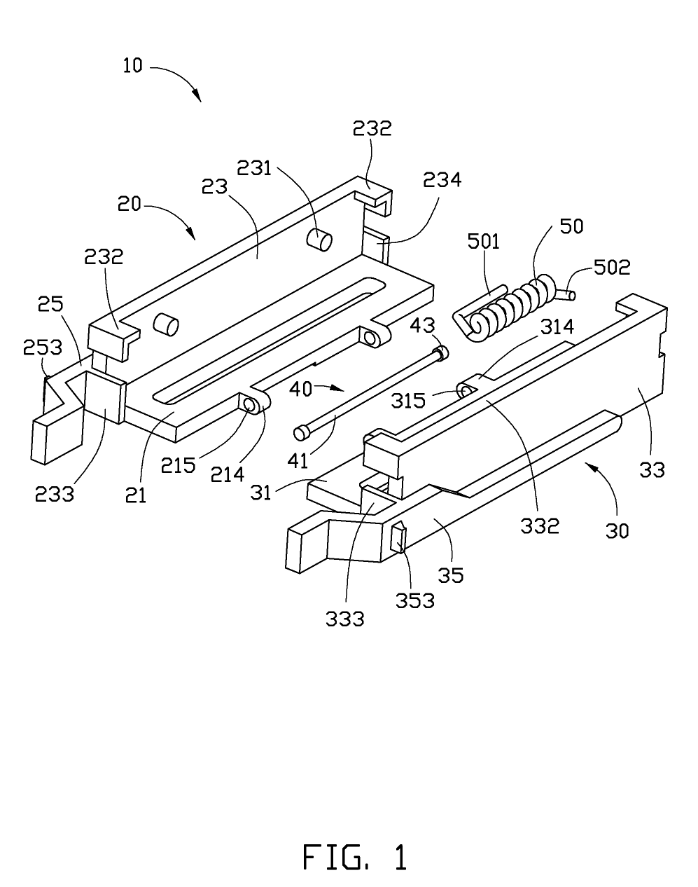

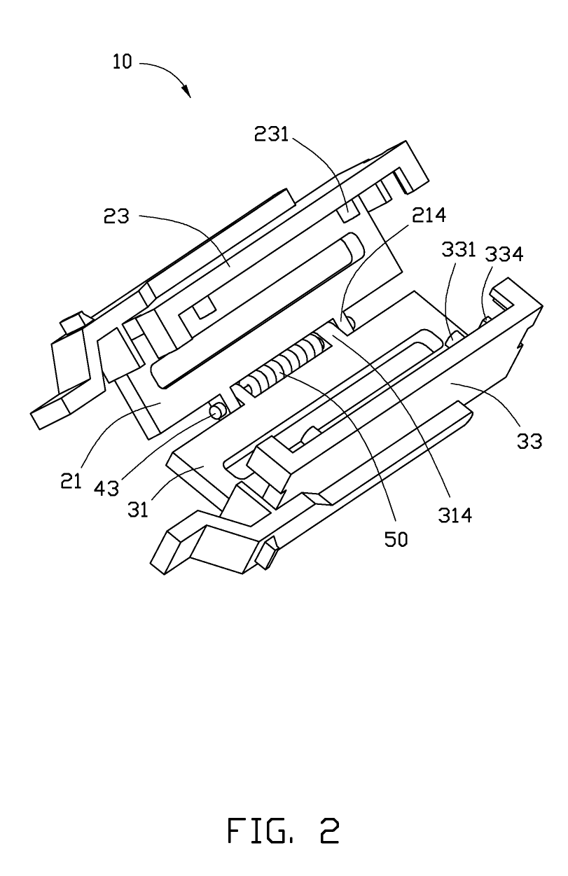

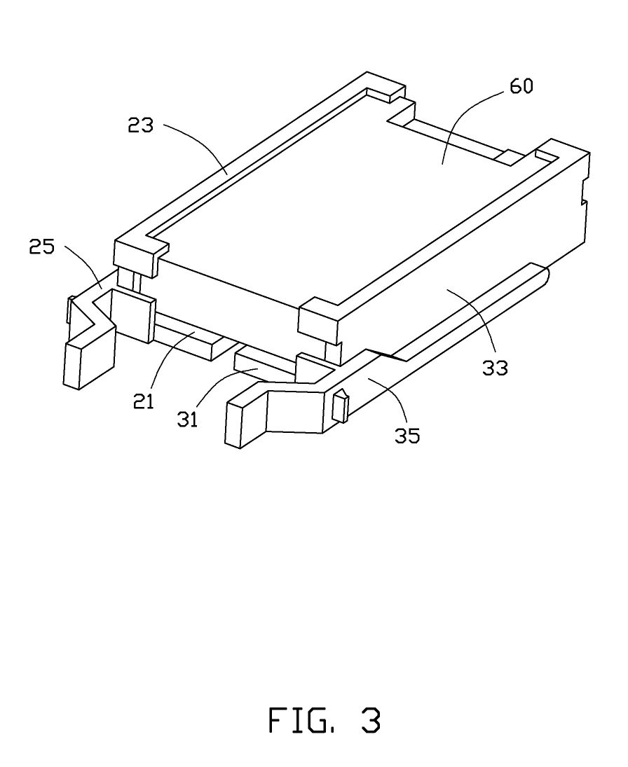

Referring to FIGS. 1-3, a mounting apparatus 10 according to an exemplary embodiment for a data storage device 60 is shown. The mounting apparatus 10 includes a first fixed member 20, a second fixed member 30, a positioning member 40, and a torsion spring 50.

The first fixed member 20 includes a first bottom plate 21, a first sidewall 23 extending up from an edge of the first bottom plate 21, and a first resilient clip 25 connected with an outer side of the first sidewall 23. The first bottom plate 21 includes a pair of first convex tabs 214 extending from a side edge of the first bottom plate 21, away from the first sidewall 23, separated by a distance and each defining a first pin hole 215 therein. The first sidewall 23 includes two first protrusions 231 extending from an inner side of the first sidewall 23, two first top block plates 232 extending inward from two opposite ends thereof, a first front block plate 233 extending inward from a front end thereof, and a first rear block plate 234 extending inward from a rear end thereof. The two first protrusions 231 are separated by a distance. The two first top block plates 232 are L-shaped. The first resilient clip 25 extends from the front end of the first sidewall 23, and includes a first raised block 253 fixed on an outer side thereof.

The second fixed member 30 includes a second bottom plate 31, a second sidewall 33 extending up from an edge of the second bottom plate 31, and a second resilient clip 35 connected with an outer side of the second sidewall 33. The second bottom plate 31 includes a pair of second convex tabs 314 extending from a side edge of the second bottom plate 31, away from the second sidewall 33, separated by a distance and each defining a second pin hole 315 therein. A distance between the pair of second convex tabs 314 is less than that between the pair of first convex tabs 214 of the first fixed member 20. The second sidewall 33 includes two second protrusions 331 extending from an inner side of the second sidewall 33, two second top block plates 332 extending inward from two opposite ends thereof, a second front block plate 333 extending inward from a front end thereof, and a second rear block plate 334 extending inward from a rear end thereof. The two second protrusions 331 are separated by a distance. The two second top block plates 332 are L-shaped. The second resilient clip 35 extends from the front end of the second sidewall 33, and includes a second raised block 353 fixed on an outer side thereof.

The positioning member 40 includes a pin 41 and two stoppers 43 removably attached to two ends of the pin 41. The pin 41 is longer than the distance between the pair of first convex tabs 214 of the first fixed member 20. A diameter of each of the two stoppers 43 exceeds a diameter of the pin 41. The first pin holes 215 of the first fixed member 20 and the second pin holes 315 of the second fixed member 30 provide a clearance fit about the pin 41.

The data storage device 60 defines two first mounting holes (not shown) in a left side thereof, and two second mounting holes (not shown) in a right side thereof. The two first mounting holes correspond to the two first protrusions 231, and the two second mounting holes correspond to the two second protrusions 331.

In assembly of the second fixed member 30 to the first fixed member 20, the pair of second convex tabs 314 of the second fixed member 30 is received between the pair of first convex tabs 214 of the first fixed member 20, and the torsion spring 50 is received between the pair of second convex tabs 314. The second pin holes 315 of the pair of second convex tabs 314 and the first pin holes 215 of the pair of first convex tabs 214 are aligned with a center of the torsion spring 50, and the pin 41 is passed through the first pin holes 215, the second pin holes 315 and the center of the torsion spring 50. The two stoppers 43 are then fixed to the two ends of the pin 41 abutting the pin 41 to maintain the torsion spring 50 and the pair of second convex tabs 314 between the pair of first convex tabs 214. Accordingly, assembly of the mounting apparatus 10 is complete. The torsion spring 50 provides a force to bias the first sidewall 23 positioned to pivot about the pin 41 towards the second sidewall 33 by one end 501 of the torsion spring 50 abutting first bottom plate 21 and the other end 502 of the torsion spring 50 abutting the second bottom plate 31.

In assembly of the data storage device 60 to the mounting apparatus 10, the first sidewall 23 moves away from second sidewall 33 by outward rotation of the first fixed member 20 and the second fixed member 30, and the torsion spring 50 is deformed. The data storage device 60 is then placed between the first fixed member 20 and the second fixed member 30. By releasing the first fixed member 20 and the second fixed member 30, the torsion spring 50 resumes to an original state, and the two first protrusions 231, the two second protrusions 331 are received in the first mounting holes and the second mounting holes of the data storage device 60 respectively. The two first top block plates 232 and the two second top block plates 332 abut a top end, a front end, and a rear end of the data storage device 60 respectively. The first front block plate 233 and the second front block plate 333 abut the front end of the data storage device 60 respectively. The first rear block plate 234 and the second rear block plate 334 abut the rear end of the data storage device 60 respectively. The first bottom plate 21 and the second bottom plate 31 abut a bottom end of the data storage device 60 respectively. Accordingly, assembly of the data storage device 60 to the mounting apparatus 10 is complete. The mounting apparatus 10 is installed in a chassis (not shown) of an electronic device by the first raised block 253 of the first resilient clip 25 and the second raised block 353 of the second resilient clip 35 engaging (not shown) with the chassis.

While the invention has been described by way of example and in terms of preferred embodiment, it is to be understood that the invention is not limited thereto. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A mounting apparatus for a data storage device, the mounting apparatus comprising:
a first fixed member comprising a first bottom plate, and a first sidewall extending up from an edge of the first bottom plate; wherein the first bottom plate comprises a pair of first convex tabs extending from a side edge of the first bottom plate, away from the first sidewall, and wherein the pair of first convex tabs each defines a first pin hole therein;
a second fixed member comprising a second bottom plate, and a second sidewall extending up from an edge of the second bottom plate; wherein the second bottom plate includes a pair of second convex tabs extending from a side edge of the second bottom plate, away from the second sidewall, and wherein the pair of second convex tabs each defines a second pin hole therein;
a torsion spring; and
a positioning member comprising a pin, wherein the pin is passed through the first pin holes of the pair of first convex tabs, the second pin holes of the pair of second convex tabs and a center of the torsion spring, and wherein the torsion spring bias the first and the second fixed members to pivot the first and the second sidewalls toward each other.

2. The mounting apparatus of claim 1, wherein the first fixed member further comprises a first resilient clip connected with a front end of the first sidewall, and the second fixed member further comprises a second resilient clip connected with a front end of the second sidewall.

3. The mounting apparatus of claim 2, wherein the first resilient clip comprises a first raised block fixed on an outer side thereof, and the second resilient clip comprises a second raised block fixed on an outer side thereof.

4. The mounting apparatus of claim 1, wherein an inner side of the first sidewall comprises at least one first protrusion extending therefrom, and an inner side of the second sidewall comprises at least one second protrusion extending therefrom, wherein the at least one first protrusion and the at least one second protrusion correspond to mounting holes of the data storage device.

5. The mounting apparatus of claim 4, wherein the number of the at least one first protrusion and the number of the at least one second protrusion are both two, and wherein the two first protrusions are separated by a distance, and the two second protrusions are separated by a distance.

6. The mounting apparatus of claim 4, wherein the first sidewall further comprises two first top block plates extending inward from two opposite ends thereof, a first front block plate extending inward from a front end thereof, and a first rear block plate extending inward from a rear end thereof.

7. The mounting apparatus of claim 4, wherein the second sidewall further comprises two second top block plates extending inward from two opposite ends thereof, a second front block plate extending inward from a front end thereof, and a second rear block plate extending inward from a rear end thereof.

8. The mounting apparatus of claim 1, wherein the pair of second convex tabs of the second fixed member is disposed between the pair of first convex tabs of the first fixed member, and the pin is longer than the distance between the pair of first convex tabs of the first fixed member.

9. The mounting apparatus of claim 8, wherein the positioning member further comprises two stoppers removably attached at two ends of the pin.

10. The mounting apparatus of claim 9, wherein a diameter of each of the two stoppers exceeds a diameter of the pin.

11. The mounting apparatus of claim 1, wherein one end of the torsion spring abuts first bottom plate and the other end of the torsion spring abuts the second bottom plate.
